(19) United States
(12) Patent Application Publication
(10) Pub. No.: US 2013/0171350 A1
(43) Pub. Date: Jul. 4, 2013

(54) High Throughput Processing Using Metal Organic Chemical Vapor Deposition

(71) Applicants: Philip A. Kraus, San Jose, CA (US); Tony P. Chiang, Campbell, CA (US); Timothy Joseph Franklin, Campbell, CA (US); Chi-I Lang, Cupertino, CA (US); Sandeep Nijhawan, Los Altos, CA (US)

(72) Inventors: Philip A. Kraus, San Jose, CA (US); Tony P. Chiang, Campbell, CA (US); Timothy Joseph Franklin, Campbell, CA (US); Chi-I Lang, Cupertino, CA (US); Sandeep Nijhawan, Los Altos, CA (US)

(73) Assignee: Intermolecular Inc., San Jose, CA (US)

(21) Appl. No.: 13/339,563

(22) Filed: Dec. 29, 2011

(51) Int. Cl. C23C 16/44; B05C 11/00

(52) U.S. Cl. 427/255.28; 118/728; 118/712

(57) ABSTRACT

A metal-organic chemical vapor deposition (MOCVD) system is provided for high throughput processing. The system comprises a chamber containing a substrate support system comprising a plurality of substrate support planets operable to support one or more substrates, and a gas emission system operable to provide a plurality of isolated environments suitable for depositing uniform layers on the substrates. The MOCVD system is operable to independently vary one or more process parameters in each isolated environment, and to provide common process parameters to all substrates for depositing one or more layers on all substrates. Methods of forming uniform layers on a substrate are provided wherein at least one of the layers is deposited in an isolated environment.

### FIELD OF THE INVENTION

One or more embodiments of the present invention relate to methods and apparatuses for practicing combinatorial MOCVD.

### BACKGROUND

The growth of high-quality crystalline semiconducting thin films is a technology of significant industrial importance, with a variety of microelectronic and optoelectronic applications, including light emitting diodes and lasers. The state of the art technique for the construction of optoelectronic devices comprising layers of semiconducting materials is metal organic chemical vapor deposition (MOCVD), in which a substrate is held at high temperature and gases which contain the elements comprising the thin film flow over and are incorporated into the growing thin film at the surface of the wafer. This technology is particularly useful for forming thin films of, for example, gallium nitride (GaN), indium nitride (InN) and aluminum nitride (AlN) thin films, their alloys and their heterostructures. In the case of GaN, the state-of-the-art may include growth temperatures of approximately 1050 C and the simultaneous use of ammonia (NH₃) and a Group III alkyl precursor gas (e.g., trimethylgallium, triethylgallium).

Due to the complexity of the MOCVD process and reactors, MOCVD suffers from a number of common problems, including system-to-system variation, run-to-run variation, and long-term stability of the deposition systems. The ability to do a large number of experimental splits for device optimization by evaluating changes in material composition, layer thicknesses, processing conditions (e.g., temperature, pressure, constituent ratios, etc.) is limited because of the lack of repeatability and the amount of unknown variation that may be happening coincidentally with the experimentally defined variations. Additionally, the number of cycles of learning in a reasonable amount of time is limited, because a typical MOCVD run takes 8 hours to complete and with the standard state of the art approaches, only one experimental condition is conducted per run.

Kuykendall et al. report the preparation of InGaN nanowires using a combinatorial approach, “Complete composition tunability of InGaN nanowires using a combinatorial approach” (Nature Vol. 6, 951-56, December 2007). The report describes the use of a low-temperature halide chemical vapor deposition to produce single crystalline InₓGa₁₋ₓN nanowires across a wide range of composition (x=0 to 1). The nanowires demonstrated tunable emission from the near-UV to the near-IR region. The authors state that the compositional tunability is due to low temperature processing and the ability of nanowire morphology to accommodate strain-relaxed growth. This method reports to suppress problematic phase separation, in contrast to the lattice effects frequently observed in materials made using conventional high-temperature MOCVD. The combinatorial parameters were limited to relative proportions of GaCl₃, InCl₃ precursors leading to a continuous gradient in the ratio of gallium to indium across the substrate. The reactor design was not compatible with planetary designs for depositing films on substrates, and provided only limited capabilities for process variations. In addition, the approach described by Kuykendall et al. relies on a substantial nonuniformity in the composition of the deposited film to create the combinatorial processing outcome. The use of within substrate nonuniformity to create a continuous in-film variation cannot be used in a combinatorial approach, where a film of substantially uniform composition is created across an entire substrate or substrate area. Thus, while Kuykendall et al. claim to disclose a combinatorial approach, the equipment disclosed is not suitable for high productivity combinatorial methods for preparation of layers on substrates.

Choo et al. describe a system of individual reactors inside a larger reactor by using local delivery and pumping of reactant gases, “Simulation-Based Design and Experimental Evaluation of a Spatially Controllable CVD Reactor” (AIChE Journal Vol. 51, No. 2, 572-84, February 2005). However, the system cannot be used in a global deposition mode, wherein all substrates or regions of a substrate within the reactor are provided the same processing conditions which result in substantially the same resultant film on all substrates or regions of a substrate, without substantially changing the processing conditions from those that are used in the combinatorial arrangement. The utility of the apparatus and methods described by Choo et al. are limited to a small range of experiments that can be performed, because the system does not support a similar environment for the processing of a substrate or substrate area in both a global deposition mode and in a combinatorial deposition mode. Thus, while Choo et al. claim to disclose a combinatorial approach, the equipment disclosed is not suitable for high productivity combinatorial methods for preparation of layers on substrates.

Li et al. report that thin films of transparent conducting cadmium tin oxide were produced by linear combinatorial synthesis using low-pressure metal-organic chemical vapor deposition, “Structure study of cadmium tin oxide thin-films prepared by linear combinatorial synthesis” (35^{th} IEEE Photovoltaic Specialists Conference, 20-25 Jun. 2010, 1933-36). Li et al. report using temperature variation across the substrate and relying on the differences in the temperature dependent rate of decomposition of the Sn and Cd metal-organic precursors. This approach results in an in-film local variation in the Sn-to-Cd concentration and of the composition dependent phase of the material deposited. However, use of within substrate nonuniformity to create in-film combinatorial results cannot be used in a combinatorial approach, where a film of substantially uniform composition is created across an entire substrate or substrate area. Thus, while Li et al. claim to disclose a combinatorial approach, the equipment disclosed is not suitable for high productivity combinatorial methods for preparation of layers on substrates.

### SUMMARY OF THE INVENTION

A metal-organic chemical vapor deposition (MOCVD) system is provided comprising a chamber containing a substrate support system and a gas emission system. The substrate support system comprises a plurality of substrate support planets operable to support one or more substrates, wherein the substrate support planets are disposed in a plane and are equidistant from a central axis oriented perpendicular to the plane. The gas-emission system comprises a gas-emitting fixture disposed at the central axis of the substrate support system, wherein the gas-emission system is operable to radially emit a plurality of gases from the gas-emitting fixture at substantially equal total flow rates across the substrate support planets. The gas emission system is operable to provide a plurality of isolated environments suitable for depositing uniform layers on the substrates. The MOCVD system is operable to independently vary one or more process parameters in each isolated environment, such as temperature, gas composition, processing time, precursor flow rates, or combinations thereof. The MOCVD system is operable to provide different process parameters for depositing one or more layers of differing composition or thickness on substrates in different isolated environments; and is operable to provide common process parameters to all substrates for depositing one or more layers on all substrates.

The system can further comprise a temperature control system for each substrate support planet operable to control temperature for each substrate area disposed thereon. The substrate support system further comprises a transport system comprising a mechanism for rotating each substrate support planet and a mechanism for revolving substrate support planets about the central axis of the substrate support, wherein the revolving can be stopped to position substrates within isolated environments. In some embodiments, the gas emission system further comprises a showerhead capable of delivering gases into each isolated environment. In some embodiments, the showerhead can comprise a plurality of sectors for delivery of differing amounts of gases to different substrates or substrate areas on a substrate support planet within an isolated environment. Each isolated environment typically encompasses an entire planet, but in some embodiments can encompass a portion of a planet. In some embodiments, the rotation of each substrate support planet can also be stopped. The transport system is capable of advancing a substrate support planet or a substrate area thereon to a desired isolated environment and holding it in that environment for a desired length of time.

The gas-emitting fixture is capable of emitting the same or different gases into each isolated environment. When the gas-emitting fixture emits different gases into each isolated environment, the revolving is stopped and each substrate support planet is positioned within an isolated environment for processing under selected process parameters. In some embodiments, the MOCVD system further comprises a metrology station for each isolated environment. The metrology station comprises in-situ monitoring by optical methods, and can be used to monitor layer deposition in each isolated environment as the processing is performed.

In some embodiments, methods of forming layers are provided comprising depositing a first layer having a first set of layer parameters on the plurality of substrate areas using MOCVD using a first set of process parameters, and depositing a second layer having a second set of layer parameters on the plurality of substrate areas using MOCVD using a second set of process parameters, wherein at least one of the layers is deposited in an isolated environment, and wherein the layers are uniform across a substrate area. In some embodiments, the layers are deposited using a substrate support system comprising a plurality of substrate support planets and a plurality of substrate areas disposed thereon. The methods can further comprise depositing one or more layers on the first and second layers using MOCVD under one or more sets of process parameters, wherein the layers are uniform across a substrate area.

The process parameters and layer parameters generally allow the deposition of layers using specific material amounts, reactant species, temperature, time, flow rate, reagent compositions, rates at which the reactions are quenched, deposition order of materials, sequence steps, hardware details, film composition, film thickness, and the like. The process parameters comprise substrate temperature, gas composition, processing time, flow rates of MOCVD precursor gases, gas pressure, or combinations thereof. In some embodiments, the set of process parameters comprise flow rates of Group III precursors, flow rates of Group V precursors, processing time, or substrate temperature, or combinations thereof. The layer parameters comprise the number of layers, the order of layers, the sum of the thicknesses of layers, the thickness of a layer, or the composition of layers, or combinations thereof.

The methods can further comprise varying the sets of process parameters in a combinatorial manner, where varying the sets of processing parameters in a combinatorial manner processes a plurality of substrate areas in a plurality of isolated environments. In some embodiments, varying the sets of processing parameters among the plurality of isolated environments in a combinatorial manner comprises applying a baseline setting for a parameter X to all substrate areas and varying the baseline setting for that parameter by a differential amount ±ΔX that can be varied independently for each isolated environment. In some embodiments, the substrate temperature, the flow rate of a precursor, or the gas composition is varied such that ΔX/X is less than 10%. In some embodiments, the processing time is varied such that ΔX/X is less than 50%.

In some embodiments, the gas composition comprises one or more Group II precursors or mixtures thereof and one or more Group VI precursors or mixtures thereof. In some embodiments, the gas composition comprises one or more Group III precursors or mixtures thereof and one or more Group V precursors or mixtures thereof. In some embodiments, the precursor gases comprise NH₃.

In some embodiments, the methods can further comprise depositing one or more layers having variable sets of layer parameters on the first and second layers using MOCVD, wherein the layers are uniform across a substrate area. The methods can further comprise varying the sets of layer parameters of layers deposited on the plurality of substrates in a combinatorial manner. In some embodiments, varying the sets of layer parameters in a combinatorial manner comprises applying a baseline setting for a parameter X to all substrate areas and varying the baseline setting for that parameter by a differential amount ±ΔX that can be varied independently for each isolated environment. In some embodiments, the film composition of a layer is varied such that ΔX/X is less than 50%. In some embodiments, the layer thickness is varied such that ΔX/X is less than 500%. In some embodiments, the number of repeats in a repeating layered structure is varied such that ΔX/X is less than 100%. In some embodiments, the total thickness of the repeating layered structure is substantially the same for all isolated environments. In some embodiments, at least one of the layers comprises a Group III/V thin film. In some embodiments, at least one of the layers comprises a Group II/VI thin film.

In some embodiments, the methods can further comprise monitoring the deposition processes occurring in each isolated environment using individual in-situ metrology stations. The process parameters can be altered as desired during the deposition process to achieve particular layer parameters in each isolated environment.

In some embodiments, process parameters and layer parameters include a baseline setting applied to all substrate areas plus or minus a differential amount that can be varied independently for each isolated environment. The differential amount between the environments is large enough to be of experimental or technical interest, but is limited to a variation that is less than an amount that would cause a disruption to MOCVD operating conditions and processing parameters such as precursor flow patterns, pumping speeds, residence times, etc. In this manner, small changes in process parameters can be effected in separate isolated environments with negligible disruption in MOCVD operation and can result in significant changes in layer parameters in separate environments during a single process run. Further, additional differential processing can be provided in the isolated environments for subsequent layers, all in parallel and without removing substrates from the MOCVD chamber.

### BRIEF DESCRIPTION OF THE DRAWINGS

FIG. 1 is a schematic diagram for implementing combinatorial processing and evaluation.

FIG. 2 is a schematic diagram for illustrating various process sequences using combinatorial processing and evaluation.

FIG. 3 illustrates a schematic diagram of a simple LED stack according to an embodiment described herein.

FIG. 4 illustrates a schematic diagram of a high throughput MOCVD system in universal mode.

FIG. 5 illustrates a schematic diagram of a high throughput MOCVD system in combinatorial mode.

FIG. 6 illustrates a schematic diagram of substrate areas that can be subjected to combinatorial processing.

FIG. 7 illustrates a schematic diagram of the processing steps possible for a prototypical LED stack.

### DETAILED DESCRIPTION

Before the present invention is described in detail, it is to be understood that unless otherwise indicated this invention is not limited to specific layer compositions. Exemplary embodiments will be described for materials produced for LED applications, but bilayers and multilayers comprising optoelectronic and microelectronic devices can beneficially be produced using the methods disclosed herein. It is also to be understood that the terminology used herein is for the purpose of describing particular embodiments only and is not intended to limit the scope of the present invention.

It must be noted that as used herein and in the claims, the singular forms “a,” “and,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. The term “about” generally refers to ±10% of a stated value.

### DEFINITIONS

The term “environment” as used herein may refer to any environment suitable for deposition of a material film or thin film on or over a substrate using a MOCVD process, or the measurement of the physical characteristics of the material film or thin film. In one embodiment, an environment may include a showerhead for delivery of precursor gases. In another embodiment, an environment may include a showerhead having a plurality of sectors for delivery of differing amounts of precursor gases to different sectors of a substrate or substrate areas. In another embodiment, an environment may include a chamber in a system having a plurality of fluidically separated chambers. In another embodiment, a system may include multiple environments, wherein each environment is fluidically separated from another environment. In another embodiment, an environment may be suitable for conducting measurements on a substrate or a thin film formed on the substrate (or target).

The terms “isolation” and “isolated” as used herein refer to the property of providing distinct processing conditions, such as controlled temperature, pressure, time of processing and precursor species and concentrations. Isolation may be complete isolation between environments or relative isolation between environments. Preferably, the relative isolation is sufficient to provide control over processing conditions within ±10%, within ±5%, within ±2%, within ±1%, or within ±0.1% of the target conditions. In some embodiments, the isolation is sufficient to reduce the presence of undesirable precursors in a particular processing step to <1%. In some embodiments, the processing conditions in each isolated environment may be identical for all isolated environments.

The term “fluidically separated” as used herein refers to the property of isolation without the presence of physical barriers. Isolated environments may be fluidically separated by the flow of gases such that there is minimal contamination of different precursors, pressures or temperatures between environments.

The term “metal nitride” as used herein may refer to a material comprising one or more metals or one or more semiconductors, and nitrogen. In certain embodiments, a metal nitride (e.g., metal nitride thin film) may have the chemical formula MₓN_{y}, wherein ‘M’ designates a metal or a semiconductor, ‘N’ designates nitrogen, and ‘x’ and ‘y’ are numbers greater than zero. In some embodiments, ‘M’ may comprise one or more metals and/or semiconductors. In embodiments, MₓN_{y} may refer to a metal nitride, such as a Group III metal nitride (e.g., gallium nitride, indium nitride, aluminum gallium nitride, indium gallium aluminum nitride). In some embodiments, a metal nitride film or thin film may comprise other materials, such as, for example, chemical dopants. Chemical dopants may include p-type dopants (e.g., magnesium, zinc) and n-type dopants (e.g., silicon, oxygen).

The term “adsorption” as used herein may refer to chemical or physical attachment of atoms or molecules on a surface, such as a substrate surface or a surface of a film or thin film on or over a substrate.

The term “substrate” as used herein may refer to any workpiece on which film or thin film formation is desired. Substrates may include, without limitation, silicon, silica, sapphire, zinc oxide, SiC, AlN, GaN, Spinel, coated silicon, silicon on oxide, silicon carbide on oxide, glass, gallium nitride, indium nitride and aluminum nitride, and combinations (or alloys) thereof. The term “substrate” or “wafer” may be used interchangeably herein.

The term “substrate area” as used herein may refer to the total area of a single substrate or the total area of a collection of substrates grouped together for collective processing. Typically, a substrate area will be approximately circular or have a length and width that are approximately equal.

The term “precursor” as used herein may refer to a liquid or vapor phase chemical having a species of interest for deposition on a substrate surface. A Group III metal precursor may include a chemical compound that includes one or more Group III metal atoms, such as one or more of Al, Ga, In, and Tl. Typical precursors include alkylated metals such as trimethyl indium or triethyl gallium. A Group V precursor may include a chemical that includes one or more Group V atoms, such as one or more of N, P, As, Sb, and Bi. Typical precursors include ammonia, phosphine or arsine. Dopant (n- or p-dopants) can be provided as precursors as well. Typical dopant precursors include SiH₄ or bis(cyclopentadienyl)magnesium (Cp₂Mg). Precursors may comprise mixtures of Group III metal precursors with N₂ and/or H₂. Precursors may comprise mixtures of Group V metal precursors with N₂ and/or H₂. A Group II metal precursor may include a chemical compound that includes one or more Group II metal atoms, such as one or more of Zn, Cd and Hg. A Group VI metal precursor may include a chemical compound that includes one or more Group VI metal atoms, such as one or more of O, S, Se and Te. Upon interaction between a substrate surface and a Group III precursor or a Group V precursor, the Group III precursor or the Group V precursor may dissociate to yield a Group III chemical (or adatoms of the Group III atom) or a Group V chemical (or adatoms of the Group V atom) on the substrate surface. Upon interaction between a substrate surface and a Group II precursor or a Group VI precursor, the Group II precursor or the Group VI precursor may dissociate to yield a Group II chemical (or adatoms of the Group II atom) or a Group VI chemical (or adatoms of the Group VI atom) on the substrate surface.

The term “substantially” as used herein refers to values within ±5% of a stated value.

The term “uniform” as used herein refers to the property of having substantially the same composition and thickness across a substrate area. The term “uniform” does not apply to a layer having a lateral gradient of composition or thickness across a substrate area.

The present Specification discloses systems and methods for high throughput processing using MOCVD. Embodiments of a combination of conventional processing and combinatorial processing in isolated environments are used to develop and investigate materials and processes for the manufacture of optoelectronic devices using MOCVD. In some embodiments of the present invention, a combination of conventional and combinatorial isolated processing techniques is used to develop and investigate materials and processes for the manufacture of LED devices. In some embodiments of the present invention, the isolated processing environments comprise processing conditions in which each combinatorial process variables is a small deviation from the average value for the same process variable, where the average is of isolated processing environments within the reactor.

The development of thin film devices for LED technologies represents a challenge in terms of the time-to-commercialization. The complexity of the system requires management of multiple kinetic pathways, thermodynamic phase equilibrium considerations, defect chemistries, and interfacial control. The large phase-space to be managed includes process parameters, source material choices, compositions, and overall integration schemes. Traditional R&D methods are ill-equipped to address such complexity, and the traditionally slow pace of R&D could limit any new material from reaching industrial relevance when having to compete with the incrementally improving performance of already established LED fabrication lines.

As part of the discovery, optimization and qualification of each unit process, it is desirable to be able to (i) test different materials, (ii) test different processing conditions within each unit process module, (iii) test different sequencing and integration of processing modules within an integrated processing tool, (iv) test different sequencing of processing tools in executing different process sequence integration flows, and combinations thereof in the manufacture of devices such as LED devices. In particular, there is a need to be able to test (i) more than one material, (ii) more than one processing condition, (iii) more than one sequence of processing conditions, (iv) more than one process sequence integration flow, and combinations thereof, collectively known as “combinatorial process sequence integration,” in a single MOCVD growth without the need for performing the equivalent number of sequential MOCVD growths for each material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

The present inventors realized that the application of high productivity combinatorial (HPC) techniques to the development and investigation of materials and processes for the manufacture of thin film devices such as LEDs can significantly improve the research and development throughput as well as result in significant cost savings in materials and time. Accordingly, systems and methods for developing and investigating materials and processes for various layers used in manufacturing III-V and II-VI thin film devices such as LED devices using HPC techniques are disclosed. The practice of combinatorial MOCVD will be described using the manufacture and testing of blue or green LEDs using InGaN/GaN multilayer device structures as exemplary embodiments, although the methods and apparatuses are not limited to this application.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD).

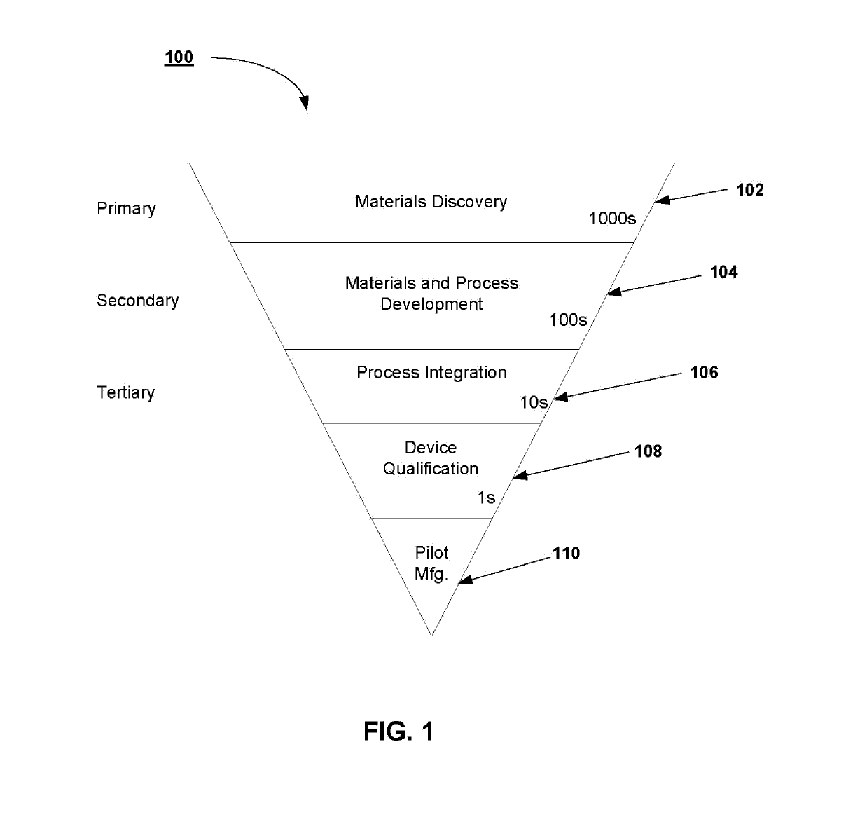

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials. In the case of MOCVD processing, integrated processes may comprise sequential layers deposited onto a substrate area to form a device structure within a single MOCVD growth.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of LED manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating a LED device. A global optimum sequence order is therefore derived and as part of this derivation, the unit processes, unit process parameters and materials used in the unit process operations of the optimum sequence order are also considered.

The embodiments described further analyze a portion or subset of the overall process sequence used to manufacture a LED device. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate area(s) that are equivalent to the structures formed during actual production of the LED device. For example, such structures may include, but are not be limited to, nucleation layers, device layers, barrier layers, cladding layers, doped and undoped layers, or any other series of layers or unit processes that create an intermediate structure found on LED devices.

While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region of substrate area. Furthermore, while different materials or unit processes may be used for corresponding layers or steps in the formation of a structure in different regions of the substrate area during the combinatorial processing, the application of each layer or use of a given unit process is substantially consistent or uniform throughout the different regions of substrate area in which it is intentionally applied. Thus, the processing is uniform within a region of the substrate area (inter-region uniformity) and between regions of substrate area (intra-region uniformity), as desired. It should be noted that the process can be varied between regions, for example, where a thickness of a layer is varied or a material may be varied between the regions, etc., as desired by the design of the experiment.

The result is a series of regions on the substrate area that contain structures or unit process sequences that have been uniformly applied within that region of substrate area and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate area can be defined as needed, but are preferably systematized for ease of tooling and design of experimentation. In addition, the number, variants and location of structures within each region of substrate area are designed to enable valid statistical analysis of the test results within each region and across regions to be performed.

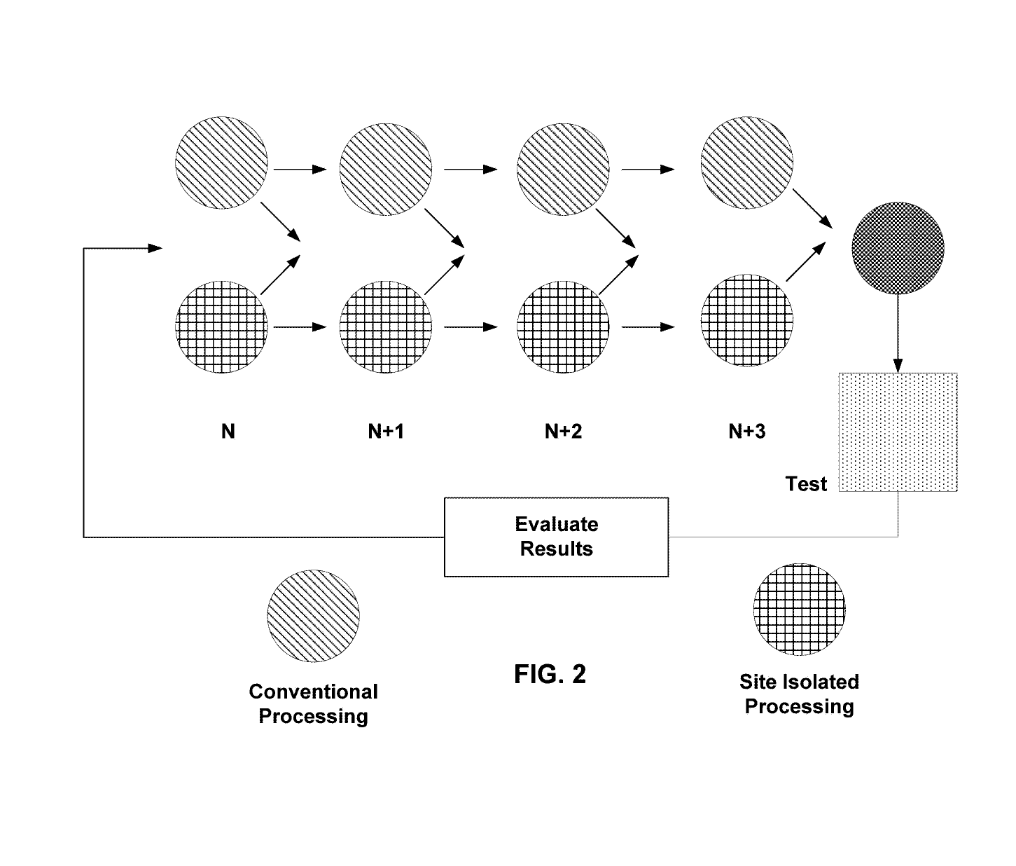

FIG. 2 is a simplified schematic diagram illustrating a general methodology for combinatorial process sequence integration that includes isolated processing and/or conventional processing of substrate area in accordance with one embodiment of the invention. In one embodiment, the substrate area is initially processed using conventional process N. In one exemplary embodiment, the substrate area is then processed using isolated process N+1. During isolated processing, an HPC module may be used, such as the HPC module described in U.S. patent application Ser. No. 11/352,077 filed on Feb. 10, 2006. The substrate area can then be processed using isolated process N+2, and thereafter processed using conventional process N+3. Testing is performed and the results are evaluated. The testing can include physical, chemical, acoustic, magnetic, electrical, optical, etc. tests. From this evaluation, a particular process from the various isolated processes (e.g. from steps N+1 and N+2) may be selected and fixed so that additional combinatorial process sequence integration may be performed using isolated processing for either process N or N+3. For example, a next process sequence can include processing the substrate area using isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above process flows can be applied to a substrate area (e.g. entire monolithic substrates, or portions of monolithic substrates, or a group of monolithic substrates) that is appropriate for the result desired.

Under combinatorial processing operations the process parameters at different regions can be controlled independently. Process parameters which can be varied include, but are not limited to, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region of substrate area to region of substrate area. It should be appreciated that these process parameters are exemplary and not meant to be an exhaustive list as other process parameters commonly used in LED manufacturing may be varied. Thus, for example, when exploring materials, a processing material delivered to a first and second region can be the same or different. If the processing material delivered to the first region of substrate area is the same as the processing material delivered to the second region of substrate area, this processing material can be offered to the first and second regions of substrate area at different concentrations.

As mentioned above, within a region of substrate area, the process conditions are substantially uniform, in contrast to gradient processing techniques which rely on the inherent non-uniformity of the material deposition. That is, the embodiments, described herein locally perform the processing in a conventional manner, e.g., substantially consistent and substantially uniform over a given substrate area, while the materials, processes, and process sequences may vary from one substrate area to another. Thus, the testing will find optimums without interference from process variation differences between processes that are meant to be the same. It should be appreciated that a region of substrate area may be adjacent to another region in one embodiment or the regions may be isolated and, therefore, non-overlapping. When the regions of substrate area are adjacent, there may be a slight overlap wherein the materials or precise process interactions are not known, however, a portion of the regions of substrate area, normally at least 50% or more of the area, is uniform and all testing occurs within that region. Further, the potential overlap is only allowed with material or processes that will not adversely affect the result of the tests. Both types of regions of substrate area are referred to herein as regions or discrete regions.

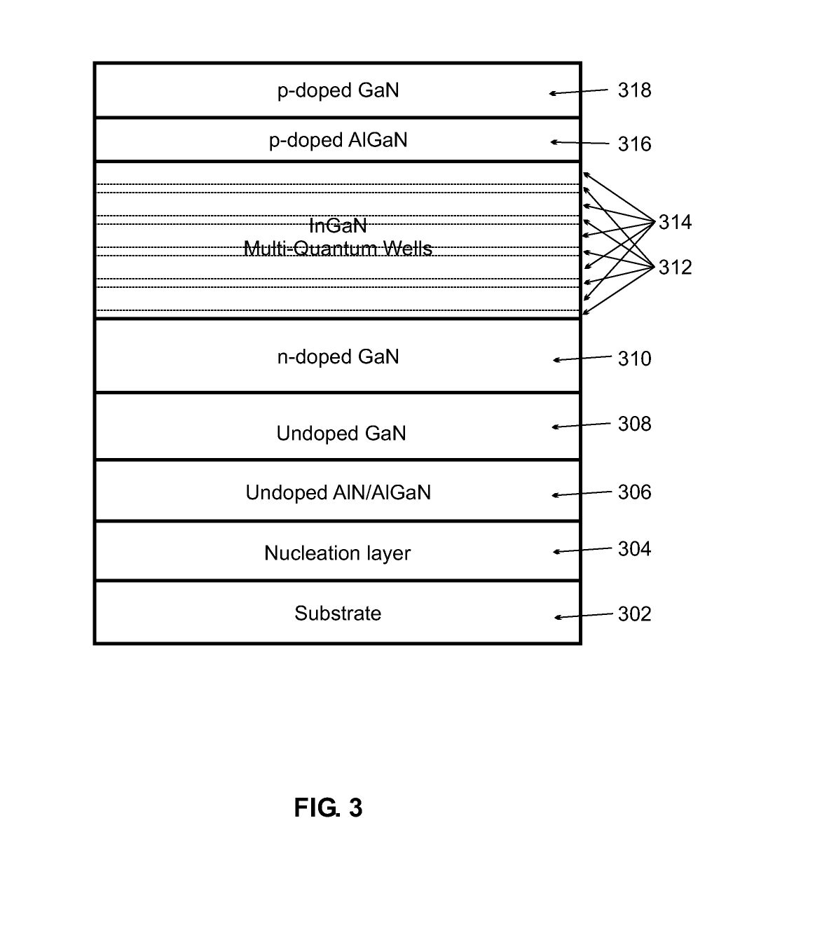

FIG. 3 illustrates a schematic diagram of a GaN LED according to an embodiment described herein. The layers are not shown to scale. A typical process for preparing the stack of layers for a LED device is as follows: A nucleation layer 304 comprising ˜30 nm of GaN is formed on a substrate, 302. Above the nucleation layer, a layer 306 comprising ˜1 μm of undoped AlN or AlGaN is formed. Above the undoped AlN or AlGaN layer, a layer 308 comprising ˜1-2 μm of undoped GaN is formed. Above the undoped GaN layer, a layer 310 comprising ˜2 μm of n-doped GaN is formed. Above the n-doped GaN layer, a series of multi-quantum wells (MQWs) 312 comprising ˜30 Å layers of InₓGa_{y}N separated by ˜100 Å barrier layers of GaN are formed. Above the MQWs, a buffer layer 314 comprising ˜100 Å of p-doped AlGaN is formed. Finally, a top layer 316 comprising ˜300 nm of p-doped GaN completes the LED structure.

Substrate 302 can be a conventional round 100 mm, 150 mm, 200 mm, 300 mm, or any other larger or smaller substrate/wafer size. In other embodiments, substrate 302 may be a square, rectangular, or other shaped substrate. One skilled in the art will appreciate that substrate 302 may be a blanket substrate, a coupon (e.g., partial wafer), or even a patterned substrate having predefined regions. In another embodiment, substrate area may be comprised of one or more substrates 302, and the substrate area may have regions defined through the processing described herein. The term region is used herein to refer to a substrate area which is, was, or is intended to be used for processing or formation of a selected material. The region can include one region and/or a series of regular or periodic regions predefined on the substrate area. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

MOCVD is a preferred method of deposition of the LED layers. The layers can be subjected to combinatorial processing in order to systematically prepare and evaluate the role of the thickness, composition and processing conditions of the layers on LED performance, as discussed further below. In order to deposit the layers using combinatorial processes, a high throughput processing MOCVD system is utilized. Embodiments of the high throughput processing MOCVD system comprise a chamber containing a substrate support system and a gas emission system. The substrate support system comprises a plurality of substrate support planets (herein also referred to as planets) operable to support one or more substrates. The substrate support planets are disposed in a plane and are approximately equidistant from a central axis that is oriented perpendicular to the plane. The gas-emission system comprises a gas-emitting fixture disposed at the central axis of the substrate support system that is operable to radially emit a plurality of gases from the gas-emitting fixture at substantially equal total flow rates across the substrate support planets. The gas emission system is operable to provide a plurality of isolated environments suitable for depositing uniform layers on the substrates. Each isolated environment typically encompasses an entire planet, but in some embodiments can encompass a portion of a planet.

In some embodiments, the gas emission system further comprises a showerhead capable of delivering gases into each isolated environment. In some embodiments, the showerhead can comprise a plurality of sectors for delivery of differing amounts of gases to different substrates or substrate areas on a substrate support planet. Showerhead technologies are well known in the art. For example, AIXTRON® SE sells the CRIUS® showerhead MOCVD systems. The showerhead can provide planet-wide delivery of reactants, or can be split into isolated areas for local delivery of reactants to separate substrate areas within each planet.

The system can further comprise a temperature control system for each substrate support planet operable to control temperature for each substrate area disposed thereon. The substrate support system further comprises a transport system comprising a mechanism operable to rotate each substrate support planet and a mechanism operable to revolve substrate support planets about the central axis of the substrate support, wherein the revolving can be stopped to position substrates within isolated environments. Any suitable motors can be used for the mechanisms; typically a plurality of “rotation” drives can be “stacked” on top of the “revolution” drive to provide all required motions. The revolution of the planets is typically performed at from 0 to about 100 rpm, and can be stopped for processing in a particular environment. The rotation of the planets is typically performed at rotation speeds of from 0 to about 100 rpm. In some embodiments, the rotation of each substrate support planet can also be stopped. The transport system is capable of advancing a substrate support planet or a substrate area thereon to a desired isolated environment and holding it in that environment for a desired length of time.

The gas-emitting fixture is capable of emitting the same or different gases into each isolated environment. The same gases can be emitted into each isolated environment when it is desirable to deposit identical layers on all substrate areas, in which case it may also be desirable to maintain the revolution of substrate support planets about the central gas emitting fixture in order to maximize uniformity of the deposition processes. Different gases can be emitted into each isolated environment when it is desirable to deposit different layers on each substrate or substrate area. When the gas-emitting fixture emits different gases into each isolated environment, the revolving is stopped so that laminar flow is maintained, and each substrate support planet is positioned within a different isolated environment for processing under selected process parameters. Thus, the system is capable of emitting the same gases into each isolated environment and is capable of emitting different gases into each isolated environment. Accordingly, layers that are the same can be deposited on substrates, and layers that are different can be deposited on substrates, in both cases without removing the substrates from the chamber. Any practical combination of the same and different layers can be deposited on substrates using the MOCVD system.

In typical operating conditions, the gas-emission system emits NH₃ at substantially equal flow rates in all radial directions, while metal-organic precursor gases may or may not be emitted toward isolated environments, depending on the processing parameters to be effected at a particular point in time. In certain embodiments, mass flow controllers are provided to independently control the gas emissions from the central gas-emitting fixture to each isolated environment. The isolated environments can be separated by the use of barriers between the environments, or can be fluidically separated, wherein there is fluid communication between the system and adjacent environments, but due to gas flow management, there is little to no cross-contamination between environments. The system further comprises a gas evacuation system including exhaust sites for removing gases from the system environment and the isolated environments so that temporal control over reactants is provided and cross-contamination between environments can be minimized.

The high throughput processing MOCVD system is operable to independently vary one or more process parameters in each isolated environment, such as temperature, gas composition, processing time, precursor flow rates, or combinations thereof. The system is operable to provide different process parameters for depositing one or more layers of differing composition or thickness on substrates in different isolated environments; and is operable to provide common process parameters to all substrates for depositing one or more layers on all substrates. The high throughput processing MOCVD system provides a plurality of isolated environments capable of providing independent process parameters, disposed about the central gas emitting fixture. Each isolated environment comprises a temperature control system for each planet. The temperature control can be provided by RF heating (induction) or resistive heating; local and independent heat boosters can be provided under each planet.

In some embodiments, the MOCVD system further comprises a metrology station for each isolated environment. In some embodiments, each isolated environment can include a metrology station for each substrate area processed within that isolated environment, so that process parameters can be monitored in situ while the process is ongoing, without removing the substrate(s) from the system. Preferably, the metrology station utilizes nondestructive methods, such as optical methods. At least one metrology station can be provided at each planet for in situ monitoring, and in some embodiments, multiple metrology stations are provided, so that different sectors of each planet can be observed for assessment of deposition layer thickness, composition, temperature, etc. In situ monitoring allows the determination of layer thickness, surface quality, deposition rate, uniformity across the substrate area, uniformity in one substrate area relative to another, composition of layers, temperature of the substrate(s) in the substrate area, and curvature induced in the substrate(s) during growth. In situ monitoring also allows accurate statistical process controls on layer deposition. Exemplary metrology stations include the capability for performing pyrometry, reflectometry, Reflectance Anisotropy Spectroscopy, and ellipsometry.

For example, and without limitation, one or more optical ports can be provided in the upper lid or the showerhead of the apparatus of the isolated environment. Typical optical ports are 1-5 mm in diameter, or more typically, 2.5 mm. The optical ports can be provided with a flow of N₂ gas to keep the ports clear of deposits. Generally, the metrology station comprises one or more lasers. Typical lasers include UV (e.g., 375 nm), blue (e.g., 405 nm, 445 nm, or 473 nm), red (e.g., 635 nm, 650 nm, or 670 nm), green (e.g., 532 nm), IR (e.g., 780 nm, 805 nm, 850 nm, 905 nm, 950 nm, 980 nm, 1064 nm, 1310 nm or 1550 nm). At any wavelength, a laser may be useful for emissivity correction for pyrometry at that wavelength. The blue laser is required in some instances for monitoring from nitrides and when used in combination, it is possible to compute composition.

A preferred metrology station monitors the development of the thin film as it is being deposited using optical techniques. A reproducible and practical method for monitoring the development of layers can be achieved using a reflectometer, sometimes also referred to as an interferometer. In its simplest form, a reflectometer consists of a laser-beam source, a beam splitter and a photo-detector. The thin film itself acts as an interferometer, generating reflected signals from the separate layer interfaces. The reflected light interferes constructively or destructively, depending on the thickness of the thin film. Commercial systems with real-time analytical capability are available from LayTec AG (Berlin, Germany) for combined pyrometer and reflectometer measurements.

Wafer curvature can also be measured in order to assess strain due to incompatibilities between layers. Measurement of wafer curvature has proven to be of particular benefit in the deposition of nitrides. In these material systems, the high growth temperatures and the differences in the thermal expansion coefficients of the epitaxial layers and the underlying substrates can result in large changes in the curvature of the wafers during growth and on subsequent cool down. Wafer curvature can typically be measured to a resolution of ±1 μm on wafers in the line of sight of the optical head. The measurement uses the location of a reflected spot on a position sensitive detector or spot separation. Commercial systems with real-time analytical capability are available from LayTec AG (Berlin, Germany) for measurements of wafer deflection.

In some embodiments, methods of forming layers are provided comprising depositing a first layer having a first set of layer parameters on the plurality of substrate areas using MOCVD using a first set of process parameters, and depositing a second layer having a second set of layer parameters on the plurality of substrate areas using MOCVD using a second set of process parameters, wherein at least one of the layers is deposited in an isolated environment, and wherein the layers are uniform across a substrate area. In some embodiments, the layers are deposited using a substrate support system comprising a plurality of substrate support planets and a plurality of substrate areas disposed thereon. The methods can further comprise depositing one or more layers on the first and second layers using MOCVD under one or more sets of process parameters, wherein the layers are uniform across a substrate area.

The process parameters and layer parameters generally allow the deposition of layers using specific material amounts, reactant species, temperature, time, flow rate, reagent compositions, rates at which the reactions are quenched, deposition order of materials, sequence steps, hardware details, film composition, film thickness, and the like. The process parameters comprise substrate temperature, gas composition, processing time, flow rates of MOCVD precursor gases, gas pressure, or combinations thereof. In some embodiments, the set of process parameters comprise flow rates of Group III precursors, flow rates of Group V precursors, processing time, or substrate temperature, or combinations thereof. The layer parameters comprise the number of layers, the order of layers, the sum of the thicknesses of layers, the thickness of a layer, or the composition of layers, or combinations thereof.

The methods can further comprise varying the sets of process parameters in a combinatorial manner, where varying the sets of processing parameters in a combinatorial manner processes a plurality of substrate areas in a plurality of isolated environments. In some embodiments, varying the sets of processing parameters among the plurality of isolated environments in a combinatorial manner comprises applying a baseline setting for a parameter X to all substrate areas and varying the baseline setting for that parameter by a differential amount ±ΔX that can be varied independently for each isolated environment. The baseline setting can refer to a universal setting, whereby all substrates or substrate areas are treated according to a particular process parameter, with variations from that baseline setting in each isolated environment.

In some embodiments, process parameters include a baseline setting applied to all substrate areas plus or minus a differential amount that can be varied independently for each isolated environment. The differential amount is large enough to be of experimental or technical interest, but is limited to a variation that is less than an amount that would cause a disruption to typical MOCVD operating conditions and processing parameters known in the art. As a non-limiting example, in the case of InGaN deposition, an experimentally meaningful change in film composition can be achieved by varying the flow of trimethyl indium from 2 standard cubic centimeters per minute (sccm) for a first isolated environment to 3 sccm for a second isolated environment, while maintaining a flow of triethyl gallium of 10 sccm and an ammonia flow of 12,000 sccm in both environments. In this example, the indium content in the film may increase by 50% (an increase of 1 part in 2), but the total flow in the reactor increases about 0.008% (an increase of 1 part in 12,010). Due to the negligible difference in the total flow between the first and second environments in this example, there will be no disruption to typical MOCVD operating conditions such as precursor flow patterns, pumping speeds, residence times, etc.

In some embodiments, the substrate temperature, the flow rate of a precursor, or the gas composition is varied such that ΔX/X is less than 10%. Thus, the temperature control system is capable of providing independent substrate area temperature control to achieve temperature T±ΔT to each isolated environment. In some embodiments, the absolute value of ΔT/T (in degrees Celsius) can be selected as follows: less than 10%, or 5% or 2%, or 1% or 0.5%. As a non-limiting example, if there are five isolated environments, the system is capable of providing one isolated environment at 750° C.; a second at 755° C.; a third at 760° C.; a fourth at 745° C., and a fifth at 740° C., providing temperature increments of 0.67% (i.e., less than 1%) and 1.3% (i.e., less than 2%) relative to the baseline temperature of 750° C.

Similarly, in some embodiments, the flow rate of a particular precursor gas can be varied in its local application to an isolated environment by specifying a given flow rate, f, and an additional flow rate Δf. Accordingly, the flow rate for a particular precursor gas can be f±Δf. In some embodiments, the absolute value of Δf/f is less than 10%, or 5% or 2%, or 1% or 0.5%. In some embodiments, a flow rate for a single precursor gas is varied. In some embodiments, the flow rates for more than one precursor gas are varied.

In some embodiments, the gas composition can also be varied from a universal gas composition to an isolated gas composition, c_{g}±Δc_{g}. In some embodiments, the absolute value of Δc_{g}/c_{g} is less than 10%, or 5% or 2%, or 1%, or 0.5%. As a non-limiting example, if there are five isolated environments, the system is capable of providing one isolated environment at a Group V precursor flow of 30,000 standard cubic centimeters per second (sccm) and a Group III precursor flow of 30 sccm, for a Group V to Group III flow ratio (herein also referred to as the V/III ratio) of 1000; a second at a V/III ratio of 1010; a third at a V/III ratio of 1020; a fourth at a V/III ratio of 990; and a fifth at a V/III ratio of 980, providing gas composition increments of 1% and 2% relative to the baseline gas composition of 1000 for the V/III ratio. In some embodiments, the gas composition comprises one or more Group II precursors or mixtures thereof and one or more Group VI precursors or mixtures thereof. In some embodiments, the gas composition comprises one or more Group III precursors or mixtures thereof and one or more Group V precursors or mixtures thereof. In some embodiments, the precursor gases comprise NH₃.

In some embodiments, processing time can also be varied from a universal exposure time to a time for each isolated environment, t±Δt. In some embodiments, the absolute value of Δt/t is less than 50%, or 25% or 10%, or 5%, or 2%. In some embodiments, the time for a particular deposition reaction to occur can be controlled by controlling the flow from a particular precursor gas source. As a non-limiting example, the on-time for a trimethyl indium gas source can be made to vary from 1 minute to 3 minutes in steps of 0.5 min to provide five different deposition times for a particular layer in each of five different isolated environments. In some embodiments, the time for a particular deposition reaction to occur can be controlled by directing the planetary wafer handling system to advance a planet to a desired isolated environment and holding it in that environment for a desired length of time. In these manners, the length of time for a particular deposition reaction to occur can be controlled, and the deposition time for each isolated environment can be set independently. When one isolated environment is being treated for a longer period of time Δt, the other isolated environments can be treated with NH₃ H₂, or N₂, or combinations thereof.

In some embodiments, the methods can further comprise depositing one or more layers having variable sets of layer parameters on the first and second layers using MOCVD, wherein the layers are uniform across a substrate area. The methods can further comprise varying the sets of layer parameters of layers deposited on the plurality of substrates in a combinatorial manner. In some embodiments, varying the sets of layer parameters in a combinatorial manner comprises applying a baseline setting for a parameter X to all substrate areas and varying the baseline setting for that parameter by a differential amount ±ΔX that can be varied independently for each isolated environment. In some embodiments, film composition can also be varied from a universal film composition to an isolated film composition, c_{f}±Δc_{f}, e.g., the film composition of a layer is varied such that ΔX/X is less than 50%. In some embodiments, the absolute value of Δc_{f}/c_{f} is less than 50%, or 25% or 10%, or 5%, or 2%. As a non-limiting example, if there are five isolated environments, the system is capable of providing to a substrate area in one isolated environment a deposited layer with In content in the alloy InₓGa₁₋ₓN where x is 0.15; a second where x is 0.16; a third where x is 0.17; a fourth where x is 0.14; and a fifth where x is 0.13, providing film composition increments of 6.67% (i.e., less than 10%) and 13.33% (i.e., less than 25%) relative to the baseline film composition where x is 0.15.

In some embodiments, film thickness can also be varied from a universal film thickness to an isolated film thickness, d±Δd, e.g., the film composition of a layer is varied such that ΔX/X is less than 500%. In some embodiments, the absolute value of Δd/d is less than 500%, or 100% or 50%, or 10%, or 5%. As a non-limiting example, if there are five isolated environments, the system is capable of providing to a substrate area in one isolated environment a deposited layer with thickness of 10 nanometers (nm); a second with thickness of 13 nm; a third with thickness of 16 nm; a fourth with thickness of 7 nm; and a fifth with thickness of 4 nm, providing film thickness increments of 30% (i.e., less than 50%) and 60% (i.e., less than 100%) relative to the baseline thickness of 10 nm.

The number of repeats in a repeating layered structure, for example the number of wells in a multi-quantum well layered structure comprised of repeated pairs of a well layer and a barrier layer, can also be varied from a universal number of repeats to an isolated number of repeats, Nᵣ±ΔNᵣ, e.g., the number of repeats in a repeating layered structure is varied such that ΔX/X is less than 100%. In some embodiments, the absolute value of ΔNᵣ/Nᵣ is less than 100%, or 50% or 20%, or 10%, or 5%. As a non-limiting example, if there are five isolated environments, the system is capable of providing to a substrate area in one isolated environment a repeating layered structure with 6 wells; a second with 8 wells; a third with 10 wells; a fourth with 4 wells; and a fifth with 2 wells, providing number of layer increments of 33.3% (i.e., less than 50%) and 66.7% (i.e., less than 100%) relative to the baseline repeating layered structure with 6 wells. In some embodiments, the total thickness of the repeating layered structure is substantially the same for all isolated environments. In some embodiments, at least one of the layers comprises a Group III/V thin film. In some embodiments, at least one of the layers comprises a Group II/VI thin film.

In some embodiments, the total thickness of a repeating layered structure may be held substantially the same while varying in an isolated matter both the number of layers and the thicknesses of one or more of the individual layers from a universal combination of the number of layers and the individual layer thicknesses. As a non-limiting example, if there are five isolated environments, the system is capable of providing to a substrate area in one isolated environment a repeated layer structure such as a multi-quantum well with 6 wells, where the wells have a thickness of 3 nm and the barriers have a thickness of 10 nm, for a total thickness of the multi-quantum well structure of 78 nm; a second with 7 wells, where the wells have a thickness of 3 nm and the barriers have a thickness of 8 nm, for a total thickness of the multi-quantum well structure of 77 nm; a third with 5 wells, where the wells have a thickness of 5 nm and the barriers have a thickness of 10 nm, for a total thickness of the multi-quantum well structure of 75 nm; a fourth with 5 wells, where the wells have a thickness of 3 nm and the barriers have a thickness of 12 nm, for a total thickness of the multi-quantum well structure of 75 nm; a fifth with 4 wells, where the wells have a thickness of 7 nm and the barriers have a thickness of 12 nm, for a total thickness of the multi-quantum well structure of 76 nm, providing variations in the number of layers and thicknesses of individual layers in the repeated layer structure while having less than 10% difference from the total thickness of the baseline repeated layer structure.

In some embodiments, the methods can further comprise monitoring the deposition processes occurring in each isolated environment using individual in situ metrology stations. The process parameters can be altered as desired during the deposition process to achieve particular layer parameters in each isolated environment. The process parameters can be controlled using any suitable machine control hardware. In some embodiments, individual analog or digital controllers can be used to set and control process parameters. In some embodiments, computing machines such as general purpose computers or programmable logic controllers can be used to consolidate the control of multiple process parameters into fewer devices (e.g., a single computing machine having a single control interface).

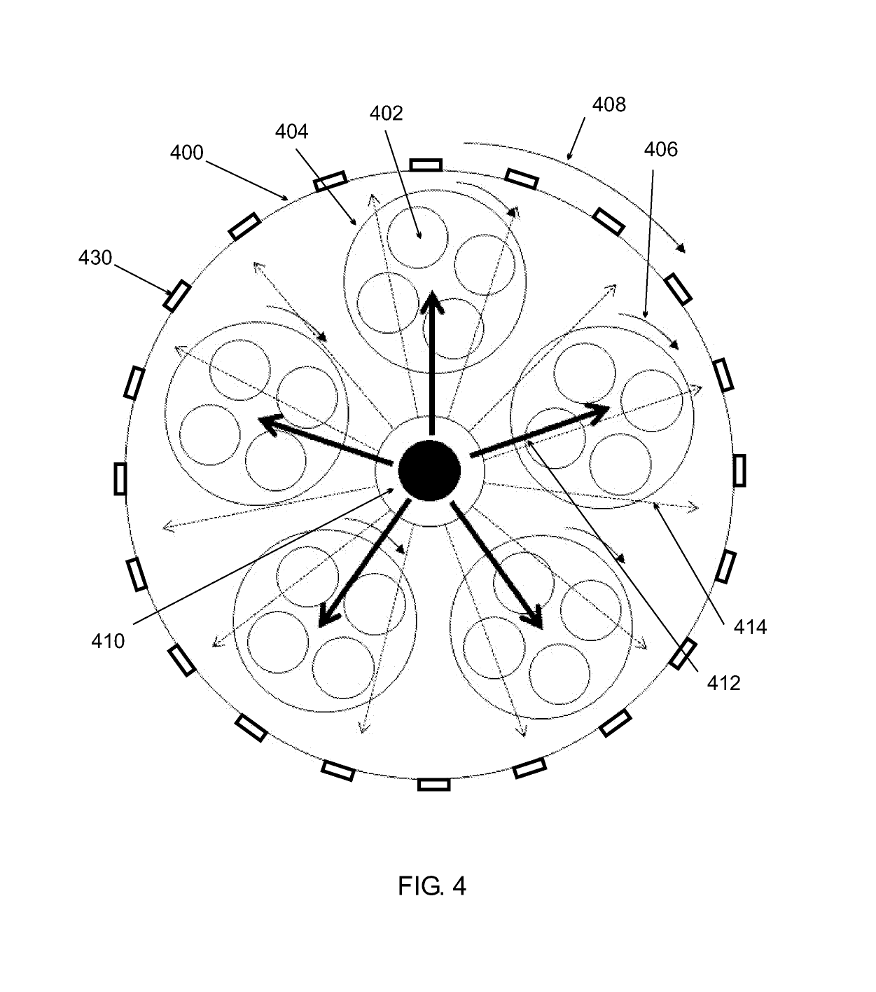

FIG. 4 illustrates a schematic diagram of a planetary combinatorial MOCVD system, 400, according to an embodiment described herein. Substrate, 402, is held on substrate support or planet, 404. Substrate support 404 rotates in direction, 406 providing planetary rotation. The global wafer handling system on which the substrate supports are disposed rotates in direction, 408, providing global rotation. The planetary rotation provides for uniform deposition of the substrate area from the uniform radial flow of process gases from the central fixture 410 to the pumping of the process gases at the periphery of the system 430. The global rotation further provides for temperature, composition and thickness uniformity across the entire substrate area. Operation as described in this embodiment results in global or non-combinatorial processing of the entire substrate area within the reactor. The planetary handling system is depicted as comprising five planets, but those skilled in the art will recognize that this number can be varied and is limited only by the size of the chamber and the size of the environments.

The central gas emitting fixture 410 is shown with arrows 412 designating the azimuthally uniform flow of Group III precursor gases, for example metal-organic precursors, and their carrier gases (center to edge flow). In some embodiments, arrows 414 designate the azimuthally uniform flows of a Group V precursor, for example NH₃. As shown in FIG. 4 with identical precursor gas compositions and flows, the system acts in universal deposition mode, i.e., all substrate area in the reactor is subjected to the same processing. Gases are evacuated from the periphery of the chamber using a plurality of exhaust sites 430 to provide a uniform pumping at the edge of the reactor, allowing laminar center-to-edge flow across the substrate supports. The substrate support can be moved in a vertical direction to alter the spacing between the isolated environment and the substrate if desired.

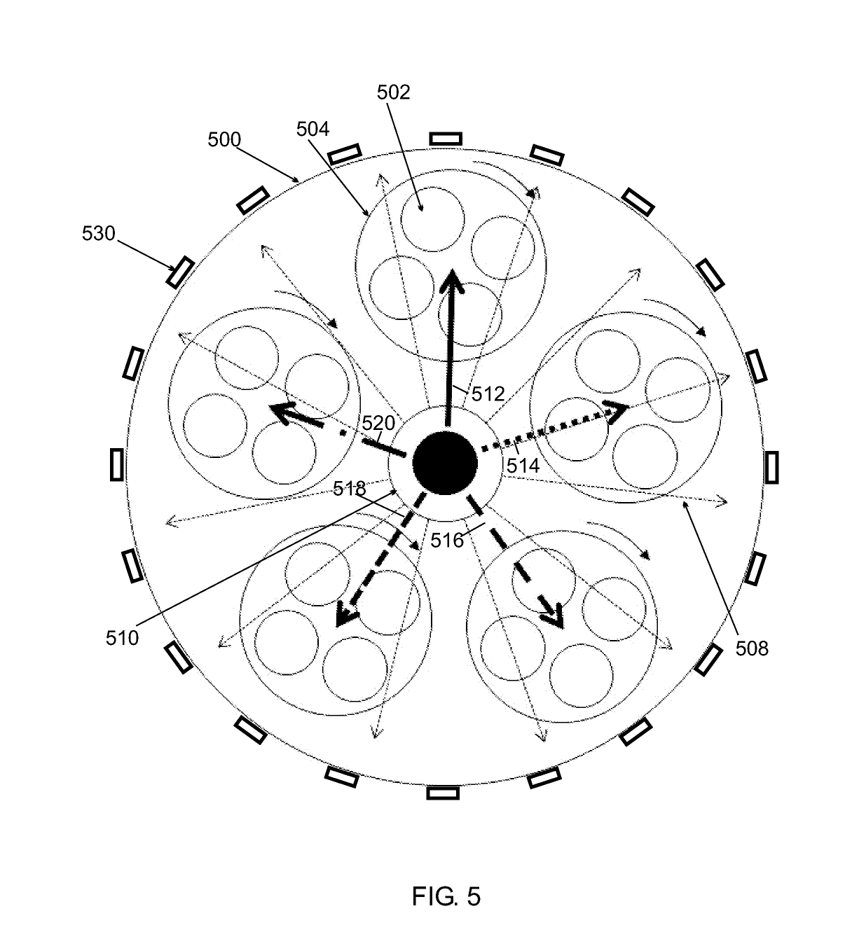

FIG. 5 illustrates a schematic diagram of a planetary combinatorial MOCVD system 500 according to an embodiment described herein. In this mode of operation, different gas precursors and flows are provided from the central gas emitting fixture toward each of the planets 504 on which substrates 502 are supported. The central gas emitting fixture 510 is shown with arrows 512, 514, 516, 518, 520 designating the uniform flow of different precursor gases in the direction of each isolated environment (center to edge flow), where planets 504 rotate in direction 506. Arrows 508 indicate the universal gas flows, in some embodiments a Group V precursor, for example NH₃. In addition, different gases can also be provided from a showerhead in each isolated environment to further refine gas concentration and flow rates for combinatorial processes. Gases can be evacuated from the periphery of the chamber using a plurality of exhaust sites 530 to provide a uniform pumping at the edge of the reactor, allowing laminar center-to-edge flow across the substrate supports. The global rotation can be stopped at an orientation where the planets are positioned in an isolated environment.

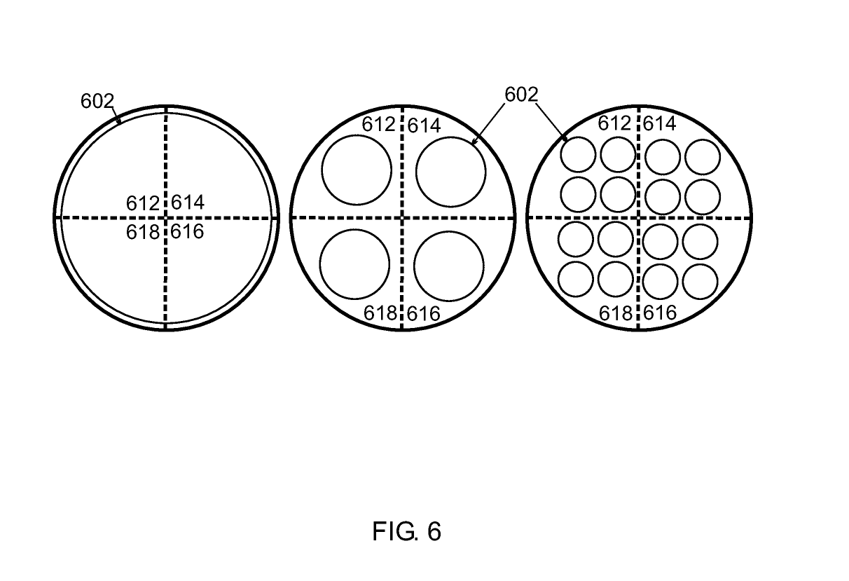

FIG. 6 illustrates four isolated environments 612, 614, 616, and 618 in a generalized combinatorial MOCVD reactor. For the same reactor, three implementations are shown where the substrate area is processed in an isolated environment. In the left, the substrate area comprises one substrate 602 which is processed in the four environments 612, 614, 616, and 618. In the middle, the substrate area comprises four substrates 602 which are processed one each in the four isolated environments 612, 614, 616, and 618. In the right, the substrate area comprises multiple substrates 602 in each of the four isolated environments 612, 614, 616, and 618.

Separate substrate areas residing in distinct isolated environments are able to be individually processed simultaneously without interference from adjacent environments due to the ability to halt global rotation while maintaining planetary rotation, in combination with the ability to provide a distinct flow of precursor gases to each planet residing in its own isolated environment, as well as the ability to provide isolated control of substrate temperature within each planet. Advantageously, the process parameters among the multiple isolated regions can be varied in a combinatorial manner.

Advantageously, the multiple MOCVD environments contain different precursors to allow a wide range of material and alloys compositions to be investigated. Additionally, the high throughput processing MOCVD system will typically include the capability for providing various gases from the central gas emitting fixture, such as O₂, NH₃, N₂, H₂, etc. A different set of process parameters can be provided for each substrate area, so that all process parameters of interest can be explored. Different layer parameters can also be investigated, as described above.

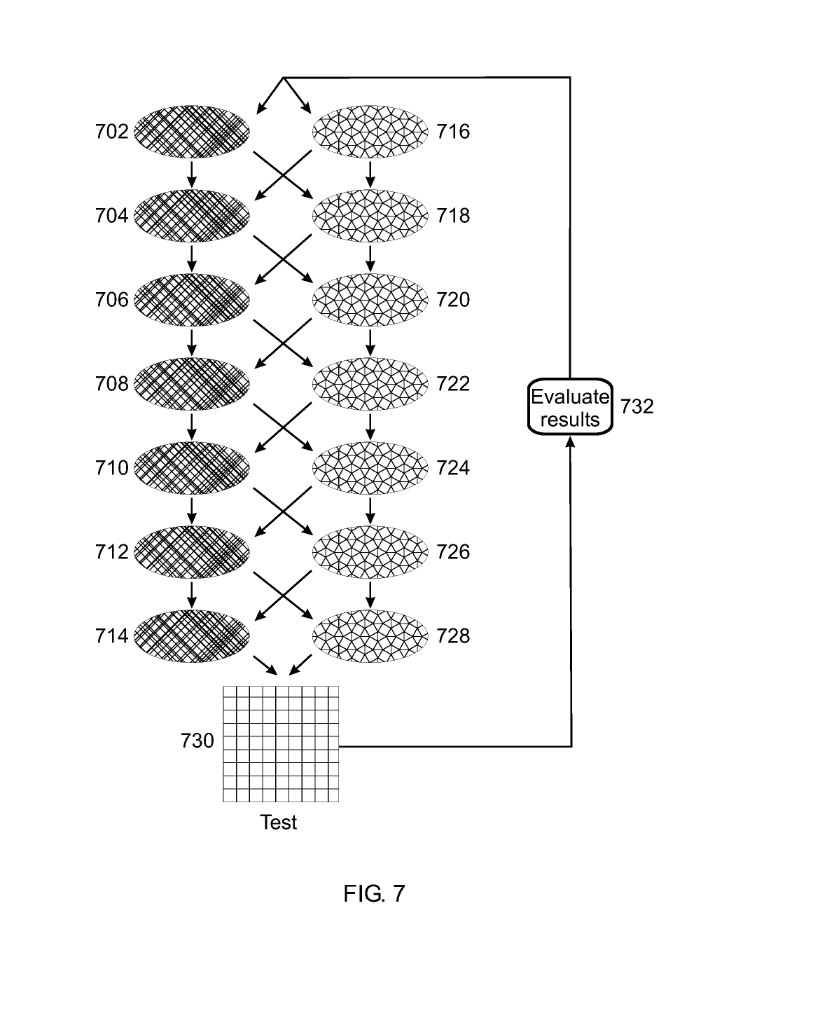

FIG. 7 illustrates a diagram of potential combinatorial process sequences for forming an LED device according to an embodiment described herein. The left column 702-714 represents conventional processing, and the right column 716-728 represents combinatorial processing. Each row represents processing of one layer. As discussed in relation to FIG. 3, numerous layers provide opportunities to apply combinatorial techniques to the development and investigation of the materials and treatments for the layers. For GaN LED devices, candidate layers are listed in Table 1 and include the undoped GaN nucleation layer (702, 716), the undoped AlN/AlGaN layer (704, 718), the doped n-GaN layer (706, 720), the quantum well layers (708, 722), barrier layers (710, 724), p-doped AlGaN, AlInN, or AlInGaN layer (712, 726), doped p-GaN layer (714, 728), as well as any other series of layers or unit processes that create an intermediate structure found on LED devices. A complete combinatorial experiment can include testing 730 and evaluating 732 before starting a new run. The parameters that are typical in existing LED processing are set forth in Table 1. The parameters that can be varied in a combinatorial manner are set forth in Table 2; these are meant to be illustrative parameters and those skilled in the art will be able to apply HPC techniques to any of the commonly used process parameters.

TABLE 1
Typical parameters for LED layers

| | Group III | | | |
|---|---|---|---|---|
| | constituent or | | | Temperature, |
| Layer | Dopants | Thickness | P, torr | °C. |
| Nucleation | Ga or Al | 30 nm | 300 | 550 |
| Layer | | | | |
| Undoped | Al, Ga | 1 μm | 100-200 | 1200-1400 |
| AlN/AlGaN | | | | |
| undoped GaN | Ga, Al, In | 1-2 μm | 300-700 | 1100-1200 |
| n-doped GaN | Ga, Al | 2 μm | 300-700 | 1100-1200 |
| | Si (dopant) | | | |
| InGaN Quantum | In, Ga | 3 nm | 300-700 | 750 |
| Well | | | | |
| InGaN Barrier | In, Ga | 10 nm | 300-700 | 750-850 |
| AlGaN blocking | Al, Ga, Mg | 10 nm | 100-200 | 950 |
| layer | (dopant) | | | |
| pGaN | Ga, Mg (dopant) | 300 nm | 300-700 | 950 |

TABLE 2
Combinatorial parameters for LED layers

| | Group III | |
|---|---|---|
| | Constituent or | |
| Layer | Dopants | Combinatorial Parameter |
| Nucleation | Ga, Al | Al content, thickness, deposition temperature, V/III flow |
| Layer | | ratio, anneal temperature, anneal time, anneal NH₃ flow |
| Undoped | Ga, Al | Al content, V/III flow ratio, thickness, temperature |
| AlN/AlGaN | | |
| undoped AlGaN | Ga, Al | Al content, V/III flow ratio, thickness, temperature |
| n-doped layer | Ga, Al | Al content, V/III flow ratio, thickness, temperature, |
| | any n-type | dopant concentration, dopant element, dopant profile |
| | dopant | |
| Quantum Well | In, Ga, Al | In content, Al content, V/III flow ratio, thickness, |
| | | temperature, number of layers |
| Barrier | In, Ga, Al | In content, Al content, V/III flow ratio, thickness, |
| | | temperature, number of layers |
| Blocking layer | In, Ga, Al, any | In content, Al content, V/III flow ratio, thickness, |
| | p-type dopant | temperature, dopant concentration, dopant element, |
| | | dopant profile |
| p-doped layer | Ga, Al, any p- | Al content, V/III flow ratio, thickness, temperature, |
| | type dopant | dopant concentration, dopant element, dopant profile |

The material composition of the layers of the LED can be varied in a combinatorial manner. The deposition conditions and the composition of the various layers, including the quantum well and barrier layers, and the blocking layer, can be investigated using HPC techniques, by varying process parameters such as temperature, exposure time, precursor concentration, precursor flow rates, NH₃ flow rate, NH₃ concentration in a neutral gas such as N₂, etc. As an example, the deposition rate and material quality is sensitive to the concentration of NH₃. In particular, a detailed study using HPC techniques to optimize the properties, including composition, of the In—Ga—Al—N quaternary material system for optimization of each of the quantum well, barrier, and blocking layers in an LED for the optimization of carrier quantum confinement and optical recombination rates is technically enabling. These are meant to be illustrative parameters and those skilled in the art will be able to apply HPC techniques to any of the commonly used process parameters.

A first layer that can be investigated using HPC techniques includes the nucleation layer. The material composition and thickness of the GaN layer may be varied in a combinatorial manner. Typically, MOCVD is the preferred method of deposition for the GaN layer. The thickness of the GaN layer can be investigated using HPC techniques by varying process parameters such as temperature, exposure time, precursor concentration, precursor flow rates, NH₃ flow rate, NH₃ concentration in a neutral gas such as N₂, etc. These are meant to be illustrative parameters and those skilled in the art will be able to apply HPC techniques to any of the commonly used process parameters.

A second layer that may be investigated using HPC techniques includes the undoped AlN/AlGaN layer. The material composition and thickness of the AlN layer may be varied in a combinatorial manner. Typically, MOCVD is the preferred method of deposition for this layer. The thickness, % Al, and V/III relative gas composition ratio can be investigated using HPC techniques by varying process parameters such as temperature, exposure time, planet rotation speed, precursor concentration, precursor flow rates, NH₃ flow rate, NH₃ concentration in a neutral gas such as N₂, etc. Additional V precursors such as arsine and phosphine can be investigated. These are meant to be illustrative parameters and those skilled in the art will be able to apply HPC techniques to any of the commonly used process parameters.

A third layer that may be investigated using HPC techniques includes the n-doped GaN. The material composition of the n-doped GaN layer may be varied in a combinatorial manner. Typically, MOCVD is the preferred method of deposition for the n-doped GaN layer. The deposition of the n-doped GaN layer by MOCVD may be investigated using HPC techniques by varying process parameters such as dopant composition (e.g., SiH₄ as precursor), temperature, exposure time, planet rotation speed, precursor concentration, precursor flow rates, NH₃ flow rate, NH₃ concentration in a neutral gas such as N₂, etc. These are meant to be illustrative parameters and those skilled in the art will be able to apply HPC techniques to any of the commonly used process parameters.

A fourth layer that may be investigated using HPC techniques includes the InGaN quantum well layer. The material composition and thickness of the quantum well layer can be varied in a combinatorial manner. Typically, MOCVD is the preferred method of deposition for this layer. The temperature, thickness, % In, and V/III gas composition ratio can be investigated using HPC techniques by varying process parameters such as temperature, exposure time, planet rotation speed, precursor concentration, precursor flow rates, NH₃ flow rate, NH₃ concentration in a neutral gas such as N₂, etc. Additional V precursors such as arsine and phosphine can be investigated. These are meant to be illustrative parameters and those skilled in the art will be able to apply HPC techniques to any of the commonly used process parameters.

A fifth layer that may be investigated using HPC techniques includes the InGaN barrier layer. The material composition and thickness of the barrier layer can be varied in a combinatorial manner. Typically, MOCVD is the preferred method of deposition for this layer. The temperature, thickness, % In, and V/III gas composition ratio can be investigated using HPC techniques by varying process parameters such as temperature, exposure time, planet rotation speed, precursor concentration, precursor flow rates, NH₃ flow rate, NH₃ concentration in a neutral gas such as N₂, etc. Additional V precursors such as arsine and phosphine can be investigated. These are meant to be illustrative parameters and those skilled in the art will be able to apply HPC techniques to any of the commonly used process parameters.

To provide the multiquantum well structure, layers four and five can be repeated any number of times. The relative composition and thicknesses of the layers and number of repeats can be varied, as well as the other combinatorial parameters mentioned above.

A sixth layer that may be investigated using HPC techniques includes the p-doped AlGaN layer. The material composition and thickness of the p-doped AlGaN layer can be varied in a combinatorial manner. Typically, MOCVD is the preferred method of deposition for this layer. The thickness, temperature, % Al, and dopant composition (e.g., Cp2Mg as precursor) of the p-doped AlGaN layer can be investigated using HPC techniques by varying process parameters such as temperature, exposure time, planet rotation speed, precursor concentration, precursor flow rates, NH₃ flow rate, NH₃ concentration in a neutral gas such as N₂, etc. Additional V precursors such as arsine and phosphine can be investigated. These are meant to be illustrative parameters and those skilled in the art will be able to apply HPC techniques to any of the commonly used process parameters.

A seventh layer that may be investigated using HPC techniques includes the p-doped GaN layer. The material composition and thickness of the p-doped GaN layer can be varied in a combinatorial manner. Typically, MOCVD is the preferred method of deposition for this layer. The thickness, temperature, and dopant composition (e.g., Cp2Mg as precursor) of the p-doped GaN layer can be investigated using HPC techniques by varying process parameters such as temperature, exposure time, planet rotation speed, precursor concentration, precursor flow rates, NH₃ flow rate, NH₃ concentration in a neutral gas such as N₂, etc. Additional V precursors such as arsine and phosphine can be investigated. These are meant to be illustrative parameters and those skilled in the art will be able to apply HPC techniques to any of the commonly used process parameters.

Returning to FIG. 7, through the use of a combination of conventional and combinatorial processing systems (i.e. systems capable of parallel processing of substrate areas in multiple isolated environments) a number of trajectories through the various systems illustrated in the flow diagram of FIG. 7 can be envisioned. The undoped GaN layer can be deposited in a conventional processing manner; since this layer is well characterized, it is omitted from FIG. 7. In FIG. 7, the GaN nucleation layer can be deposited in a conventional processing manner, 702, or in an isolated combinatorial processing manner, 716. The undoped AlN/AlGaN layer can be deposited in a conventional processing manner 704, or in an isolated combinatorial processing manner, 718. The n-doped layer can be deposited in a conventional processing manner, 706, or in an isolated combinatorial processing manner, 720. The quantum wells layers can be deposited in a conventional processing manner, 708, or in an isolated combinatorial processing manner, 722. The barrier layers can be deposited in a conventional processing manner, 710, or in an isolated combinatorial processing manner, 724. The blocking layer can be deposited in a conventional processing manner, 712, or in an isolated combinatorial processing manner, 726. The p-doped layer can be deposited in a conventional processing manner, 714, or in an isolated combinatorial processing manner, 728.

After the deposition of the various layers and subsequent processing, the various devices represented by each of the isolated regions may be tested in step 730, and the results evaluated in step 732. As discussed previously, the results can form the basis for additional cycles of investigation through HPC techniques to identify materials and process conditions that provide the optimum output and cost savings for the manufacture of LED devices.

Chemical dopants may include p-type dopants (e.g., Magnesium, Zinc, Cadmium) and n-type dopants (e.g., Silicon, Oxygen, Selenium). Other dopants of interest include carbon and many of the Lanthanides, (e.g., Europium, Erbium, Dysprosium, Lanthanum, etc.) An additional dopant of interest in the GaN system is Magnesium.

### Applications

Exemplary devices include optoelectronics devices such as light emitting diodes (LEDs), infrared LEDs, lasers, and solar cells, generally known as III/V technology. In certain preferred embodiments, the system can be used to prepare blue or green LEDs using InGaN/GaN multilayer device structures. For example, the system described herein can readily provide variations on the multi-quantum well layers and thicknesses, while maintaining other parameters constant, thereby facilitating research and development efforts in this technologically challenging area. The systems and methods are equally useful in applications involving II/VI technologies, such as CdTe photodiodes and HgCdTe photodetectors.

### Advantages

The improved systems and methods provide the capability to vary the GaN growth conditions and/or the deposition of device layers (e.g., n- and p-type doped GaN layers, multi-quantum well layers, and other associated layers such as the electron blocking layer) within a single MOCVD run. The variations can be accomplished by changing the local deposition environment in a system with multiple wafers processed per run, such that several groups of wafers receive individual processing conditions for the layers of interest in the device (e.g., LED). In this way the run-to-run variation is removed and the number cycles of learning per unit time increases because multiple experiments are conducted in parallel in one MOCVD deposition run. The combinatorial MOCVD system is constructed to allow both global conditions for all wafers in the run and to allow isolated conditions for groups of wafers for selected layers of interest in the device. Further, only one condition per each substrate area is varied so that within-wafer stress effects due to compositional changes in the film are not part of the deposited films and devices.

Conventionally performed MOCVD is expensive and time consuming. The ability to perform multiple local variations per MOCVD run provides an increase in productivity for the MOCVD system compared with traditional non-combinatorial MOCVD systems (e.g., 10 variations per MOCVD run is a ten-fold increase in productivity). In addition, due to the removal of run-to-run variability and the need to do many repeat baseline runs within a multi-run experiment (as one would need to do in a conventional, non-combinatorial MOCVD system), productivity is increased another 1.5 to 2 times. Total productivity enhancement is estimated to be 15 to 20 times when compared to conventionally performed MOCVD.

Previous work preparing thin films using MOCVD have shown that within wafer stresses can build up due to incompatibilities between layer constituents. Use of combinatorial MOCVD can be performed such that whole substrates or groups of substrates are processed within the isolated environments, so that within wafer stress effects due to compositional changes in the film are not part of the deposited films and devices. These improvements in productivity and reduced wafer stress are significant advances in the art.

It will be understood that the descriptions of one or more embodiments of the present invention do not limit the various alternative, modified and equivalent embodiments which may be included within the spirit and scope of the present invention as defined by the appended claims. Furthermore, in the detailed description above, numerous specific details are set forth to provide an understanding of various embodiments of the present invention. However, one or more embodiments of the present invention may be practiced without these specific details. In other instances, well known methods, procedures, and components have not been described in detail so as not to unnecessarily obscure aspects of the present embodiments.

What is claimed is:

1. A metal-organic chemical vapor deposition (MOCVD) system comprising
a chamber, a substrate support system, and a gas emission system;
wherein the substrate support system comprises a plurality of substrate support planets operable to support one or more substrates, wherein the substrate support planets are disposed in a plane and are equidistant from a central axis of the substrate support system, wherein the central axis is perpendicular to the plane;
wherein the gas-emission system comprises a gas-emitting fixture disposed at the central axis of the substrate support system, wherein the gas-emission system is operable to radially emit a plurality of gases from the gas-emitting fixture at substantially equal total flow rates across the substrate support planets;
wherein the substrate support system and the gas emission system are contained within the chamber;
wherein the gas emission system is operable to provide a plurality of isolated environments suitable for depositing uniform layers on the substrates; and
wherein the system is operable to independently vary one or more process parameters in each isolated environment.

2. The system of claim 1, wherein the MOCVD system is operable to provide different process parameters for depositing one or more layers of differing composition or thickness on substrates in different isolated environments; and
wherein the MOCVD system is operable to provide common process parameters to all substrates for depositing one or more layers on all substrates.

3. The system of claim 1, wherein the process parameters comprise temperature, gas composition, processing time, precursor flow rates, or combinations thereof.

4. The system of claim 1, further comprising a temperature control system for each substrate support planet operable to control temperature for each substrate disposed thereon.

5. The system of claim 1, wherein the substrate support system further comprises a transport system comprising a mechanism for rotating each substrate support planet and a mechanism for revolving substrate support planets about the central axis of the substrate support, wherein the revolving can be stopped to position substrates within isolated environments.

6. The system of claim 5, wherein the transport system is capable of advancing a substrate support planet or a substrate thereon to a desired isolated environment and holding it in that environment for a desired length of time.

7. The system of claim 1, wherein the gas-emitting fixture is capable of emitting the same or different gases into each isolated environment, and wherein when the gas-emitting fixture emits different gases into each isolated environment, each substrate support planet is positioned within an isolated environment.

8. The system of claim 1, further comprising a metrology station for each isolated environment.

9. A method of forming layers comprising
depositing a first layer having a first set of layer parameters on a plurality of substrates using metal-organic chemical vapor deposition (MOCVD) using a first set of process parameters, and
depositing a second layer having a second set of layer parameters on the plurality of substrates using MOCVD using a second set of process parameters;
wherein at least one of the layers is deposited in an isolated environment, and
wherein the layers are uniform across a substrate of the plurality of substrates.

10. The method of claim 9, wherein the process parameters comprise temperature, gas composition, processing time, flow rates of MOCVD precursor gases, gas pressure, or combinations thereof.

11. The method of claim 9, further comprising varying the sets of processing parameters among the plurality of isolated environments in a combinatorial manner, wherein the varying comprises applying a baseline setting for a parameter X to all substrates and varying the baseline setting for that parameter by a differential amount ±ΔX that can be varied independently for each isolated environment.

12. The method of claim 11, wherein X is the substrate temperature, or the flow rate of a precursor, or the gas composition, and ΔX/X is less than 10%.

13. The method of claim 11, wherein X is the processing time and ΔX/X is less than 50%.

14. The method of claim 12, wherein the gas composition comprises one or more Group II precursors or mixtures thereof and one or more Group VI precursors or mixtures thereof.

15. The method of claim 12, wherein the gas composition comprises one or more Group III precursors or mixtures thereof and one or more Group V precursors or mixtures thereof.

16. The method of claim 9, wherein the layer parameters comprise the number of layers, the order of layers, the sum of the thicknesses of layers, the thickness of a layer, or the composition of layers, or combinations thereof.

17. The method of claim 9, further comprising varying the sets of layer parameters of layers deposited on the plurality of substrates in a combinatorial manner, wherein the varying comprises applying a baseline setting for a parameter X to all substrates and varying the baseline setting for that parameter by a differential amount ±ΔX that can be varied independently for each isolated environment.

18. The method of claim 17, wherein X is film composition of a layer and ΔX/X is less than 50%.

19. The method of claim 17, wherein X is layer thickness and ΔX/X is less than 500%.

20. The method of claim 17, wherein X is number of repeats in a repeating layered structure and ΔX/X is less than 100%.
